(19) United States
(12) Patent Application Publication
(10) Pub. No.: US 2016/0172521 A1
(43) Pub. Date: Jun. 16, 2016

(54) SOLAR CONCENTRATOR WITH MICROREFLECTORS

(71) Applicant: CORNING INCORPORATED, Corning, NY (US)

(72) Inventor: Jacques Gollier, Redmond, WA (US)

(21) Appl. No.: 14/904,539

(22) PCT Filed: Jul. 14, 2014
(86) PCT No.: PCT/US14/46465

§ 371 Date: Jan. 12, 2016

Related U.S. Application Data
(60) Provisional application No. 61/847,806, filed on Jul. 18, 2013.

(51) Int. Cl. H01L 31/054; H01L 31/052

(52) U.S. Cl. CPC H01L 31/0547; H01L 31/0521

(57) ABSTRACT

A solar concentrator for a solar panel that has a transparent substrate with photovoltaic cells arranged spaced apart in contact with the bottom of the substrate. Microreflectors arranged between the photovoltaic cells and in contact with the bottom of the substrate receive a portion of the sunlight incident upon the solar panel and direct the sunlight portion back through the substrate. The reflected sunlight portion reflects from the substrate top surface by total-internal reflection, and this light is directed to one or more of the photovoltaic cells.

This application claims the benefit of priority under 35 U.S.C. §119 of U.S. Provisional Application Ser. No. 61/847806, filed on Jul. 18, 2013, the content of which is relied upon and incorporated herein by reference in its entirety.

### FIELD

The present disclosure relates to solar concentrators for photovoltaic-based solar panels, and in particular to a solar concentrator that utilizes microreflectors.

### BACKGROUND

Solar power sources include solar panels that include photovoltaic (PV) cells that convert solar energy into electrical energy by the photoelectric effect. To increase the efficiency of solar panels, solar concentrators can be used to collect sunlight that would not otherwise be incident upon the PV cells and direct it to the PV cells. The two main types of solar concentrators are based on parabolic reflectors and Fresnel refractive lenses.

A shortcoming of many solar concentrators is that they add substantial size and cost to the solar panel. Accordingly, there is a need for solar concentrators that can be formed as an integral part of or otherwise be combined with a solar panel while also minimizing the size and cost of the solar panel. Also, conventional solar concentrators present some practical problems, not the least of which is that because they are exposed to harsh environments, their efficiency rapidly decreases as a function of time. Furthermore, cleaning a solar panel that has many non-flat elements is time consuming and labor intensive.

### SUMMARY

An aspect of the disclosure is directed to a solar concentrator for concentrating sunlight onto photovoltaic cells of a solar panel. The solar concentrator includes: a substantially planar substrate that is substantially transparent to the sunlight, the substrate having top and bottom surfaces, wherein the photovoltaic cells are arranged spaced apart from each other and in contact with the bottom surface; one or more microreflectors arranged between the photovoltaic cells and in contact with the bottom surface, the microreflectors having angled facets that receive the sunlight through the substrate and reflect the sunlight to the top surface at a reflectance angle that is greater than a total-internal reflection (TIR) critical angle for the substrate top surface. The sunlight reflected by TIR at the substrate top surface is directed to one or more of the photovoltaic cells.

Another aspect of the disclosure is a solar panel for converting sunlight into electrical energy. The solar panel includes: a substantially planar substrate that is substantially transparent to the sunlight and that has top and bottom surfaces; photovoltaic cells arranged spaced apart from each other and in contact with the bottom surface; microreflectors arranged between the photovoltaic cells and in contact with the bottom surface, the microreflectors having angled facets that receive a first portion of the sunlight through the substrate and reflect the first portion of the sunlight to the top surface at a reflectance angle that is greater than a total-internal reflection (TIR) critical angle for the substrate top surface, and wherein the first portion of the sunlight reflected by TIR at the substrate top surface is directed to one or more of the photovoltaic cells. A second portion of the sunlight is directly received by the photovoltaic cells.

Another aspect of the disclosure is a method of concentrating sunlight onto photovoltaic cells of a solar panel wherein the photovoltaic cells are arranged spaced apart and in contact with a bottom surface of a substrate. The method includes: passing the sunlight through the substrate to irradiate the photovoltaic cells, wherein a portion of the sunlight does not irradiate the photovoltaic cells; reflecting the portion of the sunlight back through the substrate to the top surface of the substrate at a reflectance angle that is greater than a total-internal reflection (TIR) critical angle for the substrate top surface; and directing the TIR light from the top substrate surface to one or more of the photovoltaic cells.

Another aspect of the disclosure is a method of concentrating sunlight onto photovoltaic cells of a solar panel wherein the photovoltaic cells are arranged spaced apart and in contact with a bottom surface of a substrate having a chamber. The method includes: passing the sunlight through the substrate and chamber to irradiate the photovoltaic cells, wherein a portion of the sunlight does not irradiate the photovoltaic cells; reflecting the portion of the sunlight back through the substrate and chamber to the top surface of the substrate at a reflectance angle that is greater than a total-internal reflection (TIR) critical angle for the substrate top surface; directing the TIR light from the top substrate surface and through the chamber to one or more of the photovoltaic cells; and flowing a cooling liquid through the chamber to cool the photovoltaic cells.

Additional features and advantages are set forth in the Detailed Description that follows, and in part will be readily apparent to those skilled in the art from the description or recognized by practicing the embodiments as described in the written description and claims hereof, as well as the appended drawings. It is to be understood that both the foregoing general description and the following Detailed Description are merely exemplary, and are intended to provide an overview or framework to understand the nature and character of the claims.

### BRIEF DESCRIPTION OF THE DRAWINGS

The accompanying drawings are included to provide a further understanding, and are incorporated in and constitute a part of this specification. The drawings illustrate one or more embodiment(s), and together with the Detailed Description serve to explain principles and operation of the various embodiments. As such, the disclosure will become more fully understood from the following Detailed Description, taken in conjunction with the accompanying Figures, in which:

FIG. 1 is an elevated view of an example photovoltaic-based solar panel according to the disclosure, shown being illuminated with sunlight;

FIG. 2 is a close-up cross-sectional view as taken in the y-z plane of a portion of the solar panel of FIG. 1;

FIG. 3 is a top-down view of an example solar panel showing an example configuration of the array of PV cells and the array of microreflectors that reside between the PV cells, as seen through the transparent substrate;

FIG. 4 is a close-up view similar to FIG. 2 but illustrating an example wherein the light rays reflected by microreflector and by the top surface of the substrate are made incident upon the immediately adjacent PV cells;

FIG. 5 is a close-up view similar to FIG. 2 and shows an example microreflector with a 30°-60°-90° geometry;

FIG. 6 is similar to FIG. 5 and shows farther-away view and illustrates how light rays reflected by the microreflector undergo symmetrical reflection in opposite directions at +θ and −θ, and also illustrates an example substrate formed by two thin sheets;

FIG. 7 is similar to FIG. 6 and shows a close-up view of an example microreflector wherein the facet angles β=φ=30°;

FIG. 8 is a plot of the collection efficient CE (%) as a function of the light ray incidence angle α, with the different curves representing different PV cells;

FIG. 9 is a close-up view similar to FIG. 5 and shows how the difference in refractive indices nₘ and nₛ between the microreflector and the substrate causes reflected light from the microreflector to refract at the interface between the substrate bottom surface and the top surface of the microreflector;

FIG. 10 illustrates an example embodiment similar to that shown in FIG. 6, wherein the substrate comprises two thin sheets that define a chamber shown as containing flowing liquid; and

FIG. 11 is similar to FIG. 1 and illustrates an embodiment of a cooled solar panel that employs the solar concentrator configuration of FIG. 10.

### DETAILED DESCRIPTION

Reference is now made in detail to various embodiments of the disclosure, examples of which are illustrated in the accompanying drawings. Whenever possible, the same or like reference numbers and symbols are used throughout the drawings to refer to the same or like parts. The drawings are not necessarily to scale, and one skilled in the art will recognize where the drawings have been simplified to illustrate the key aspects of the disclosure.

The claims as set forth below are incorporated into and constitute part of this Detailed Description.

The entire disclosure of any publication or patent document mentioned herein is incorporated by reference.

Cartesian coordinates are shown in some of the Figures for the sake of reference and are not intended to be limiting as to direction or orientation.

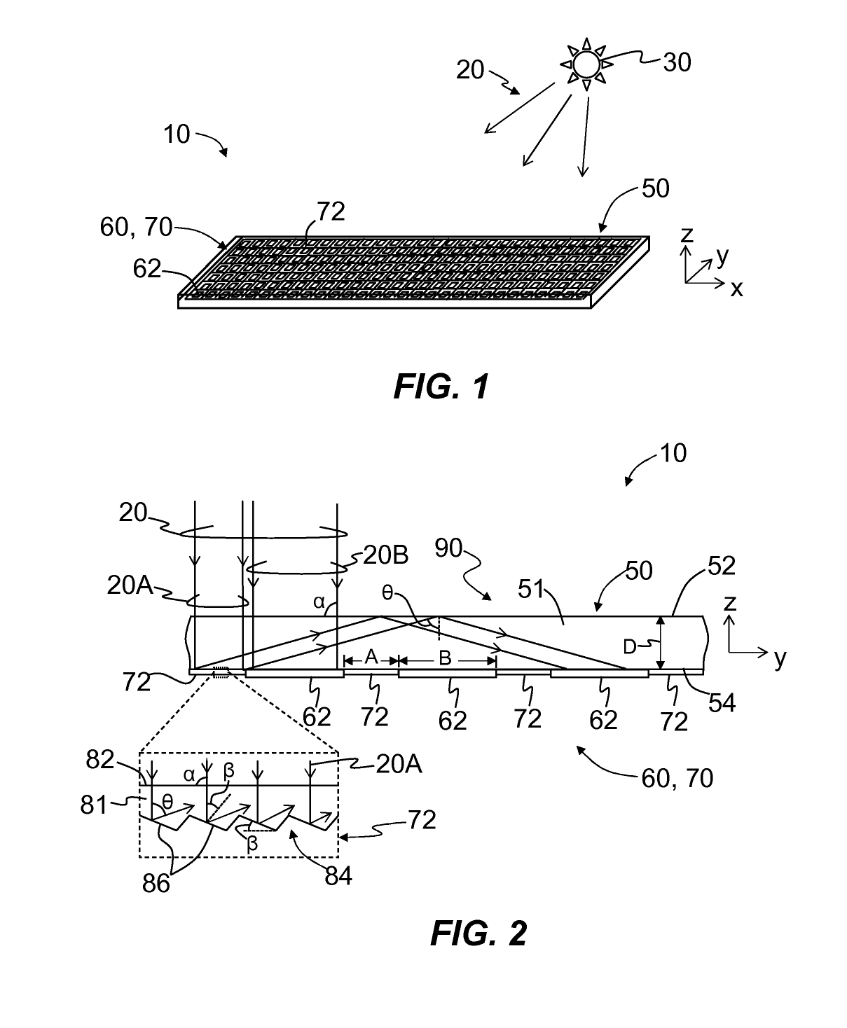

FIG. 1 is an elevated view of an example photovoltaic-based solar panel 10 according to the disclosure, shown being illuminated with sunlight (light rays) 20 from the sun 30. FIG. 2 is a close-up cross-sectional view of a portion of solar panel 10 of FIG. 1 as taken in the y-z plane. Solar panel 10 includes a generally planar substrate 50. In one example, substrate 50 has a solid body 51 with generally planar and parallel top and bottom surfaces 52 and 54 that define a substantially constant substrate thickness D. Substrate body 51 is substantially transparent to sunlight 20 and has a refractive index nₛ. In an example, thickness D is in the range 5 mm≦D≦20 mm, while in another example the thickness D is in the range 6 mm≦D≦12 mm, while in yet another example the thickness D is in the range 7 mm≦D≦10 mm.

In an example, substrate 50 is made from a chemically strengthened glass, such as formed by an ion-exchange process. In an example, substrate 50 is made of Gorilla® glass, made by Corning, Inc. of Corning N.Y.

Solar panel 10 includes an array 60 of photovoltaic (PV) cells 62 arranged in contact with bottom surface 54 of substrate 50. PV cells 62 are spaced apart and have a dimension B. In an example, PV cells 62 are square so that they have an area of B². Solar panel 10 also includes a microreflector array 70 that includes microreflector elements (“microreflectors”) 72 disposed between PV cells 62 and that are in contact with bottom surface 54. In an example embodiment, microreflectors 72 have a dimension A. In an example, an index-matching fluid (not shown) can be used to enhance the optical contact between microreflectors 72 and bottom surface 54 of substrate 50, as well as the optical contact between PV cells 62 and the bottom surface. Thus, the presence of an index-matching fluid does not obviate the condition that the microreflectors 72 and PV cells 62 are “in contact” with substrate bottom 54. Substrate 50 and microreflectors 72 constitute a solar concentrator 90.

FIG. 2 includes a close-up inset that shows a portion of an example microreflector 72 that includes a body 81 of refractive index nₘ and that has a planar top surface 82 and a bottom surface 84. Bottom surface 84 includes facets 86 each having a facet angle β, as shown in the close-up inset of FIG. 1 and as discussed in greater detail. Facets 86 also have additional facet angles φ and ρ (see FIG. 5), and facet angle β is considered herein as the main facet angle. In an example, facets 86 are large relative to visible wavelengths of light (nominally, 500 nm), e.g., 2 microns are larger, or 10 microns or larger, or 50 microns or larger. Having facets 86 that are substantially larger than the wavelength of visible light serves to avoid diffraction effects, allowing the microreflectors to operate mainly based on the principle of specular reflection.

In an example, microreflectors 72 are fabricated using a diamond turning process. The diamond turning process includes fabricating a master that has the negative of bottom surface 84. The master is then used to replicate bottom surface 84 on a transparent substrate (film) through roll-to-roll process. The processed film can then be bonded to bottom surface 54 of substrate 50. Typical feature sizes (e.g., facets 86) that can be formed using the above diamond turning process is on the order of 50 microns and larger.

Regardless of the process used to fabricate microreflectors 72, one important parameter that can affect collector system performance is facet roughness. Processes like diamond turning and roll-to-roll replication tend to introduce some surface roughness. The surface roughness can end up scattering a portion of light 20A. In example where it is preferred to control the amount of light scattering to be below 20% (i.e., the specular reflection component is at least 80%), the surface roughness needs to be less than about 20 nm RMS (Root Mean Square).

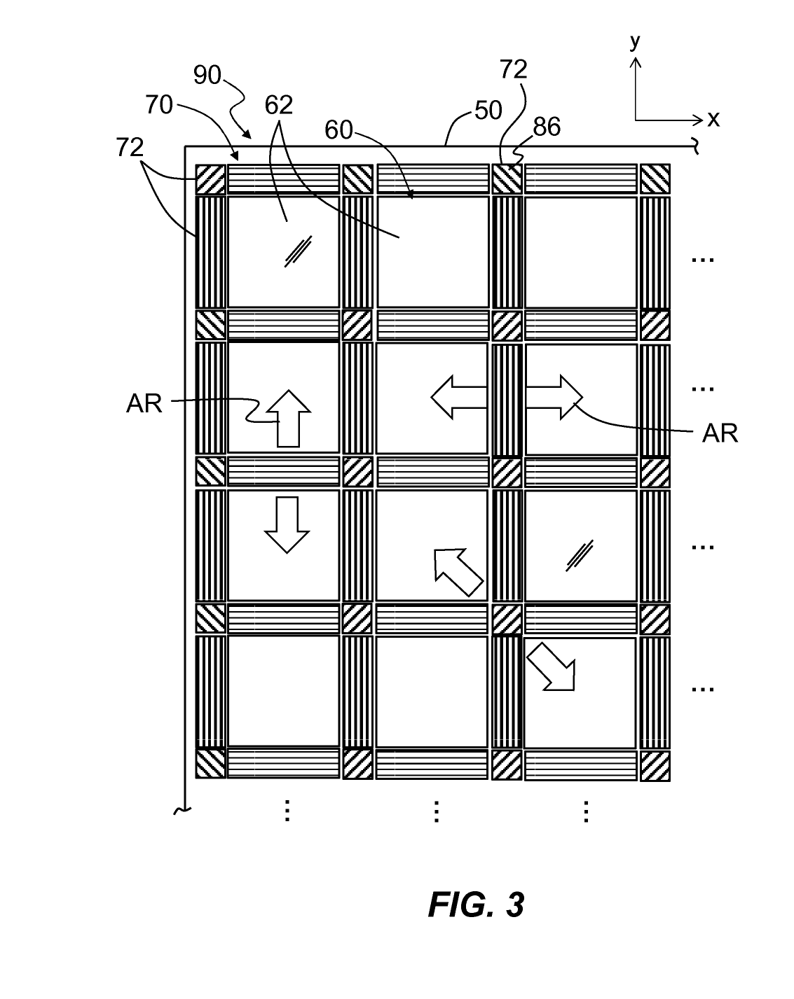

FIG. 3 is a top-down view of an example configuration of solar panel 10 that shows an example configuration for array 60 of PV cells 62 and array 70 of microreflectors 72 as viewed through substrate 50. The spaced-apart PV cells 62 form a checkerboard pattern, and the microreflectors 72 reside within the spaces between the PV cells. The arrows AR are explained below.

With reference again to FIG. 2, a (first) portion 20A of sunlight 20 passes through substrate 50 and is incident upon microreflectors 72 while another (second) portion 20B of the sunlight is directly received by (i.e., irradiates) PV cells 62 through substrate 50. The sunlight portion 20B that is directly received by PV cells 62 through substrate 50 is absorbed thereby and converted to electrical energy (e.g., an electrical current). However, the sunlight portion 20A that is incident upon microreflectors 72 needs to be redirected to be incident upon one or more of PV cells 62 so that this sunlight portion can also be converted into electrical energy. The sunlight portions 20A and 20B are also referred to below as light rays 20A and 20B, respectively.

Light rays 20A are shown as totally internally reflecting from facets 86 at a reflectance angle θ measured relative to normal incidence angle α=0° at top surface 82 of microreflector 72. For this condition to occur, the facet angle β needs to be greater than a critical facet angle ρ_{C} that results in total-internal reflection (TIR) of light rays 20A for at least a range of angles around normal incidence to top surface 82.

The facet angle β for microreflectors 72 is related to the reflectance angle θ by the relation θ=2β. The critical facet angle β_{C} is determined by the TIR angle for light rays 20A that reflect by TIR from the microreflector facets 86. Light rays 20A that reflect from facets 86 are directed to the substrate top surface 52 and are shown as undergoing TIR at the top surface. For this condition to occur, the reflectance angle θ must be greater than the critical reflectance angle θ_{C} for TIR, i.e., θ>θ_{C}.

The critical angle θ_{C}=arcsin(1/nₛ), wherein 1 is the index of air, which is assumed to be the medium residing above substrate top surface 52. For a glass substrate 50, nₛ≈1.5, so that θ_{C}≈42°. Thus, the corresponding critical facet angle β_{C}=θ_{C}/2≈21° for the example case where nₘ=nₛ.

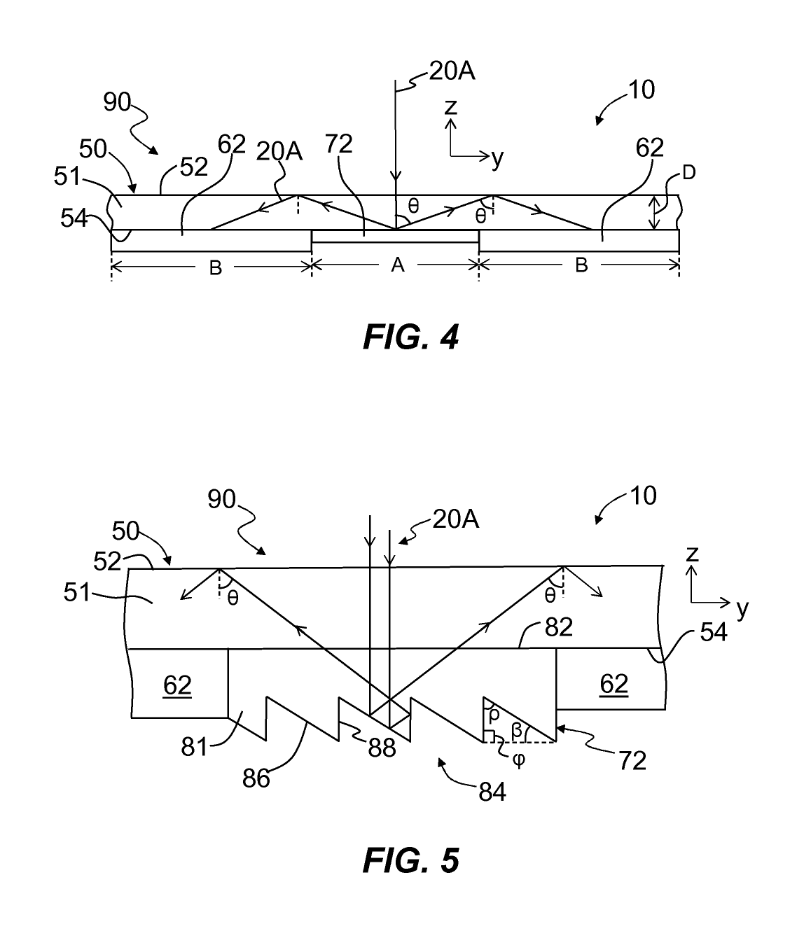

Light rays 20A reflected by TIR from top surface 52 of substrate 50 at the reflectance angle θ need to made incident upon one or more PV cells 62. FIG. 4 is a close-up view of a portion of solar panel 10 similar to FIG. 2 but illustrating an example wherein the light rays 20A reflected by microreflector 72 and by the top surface 52 of substrate 50 are made incident upon the immediately adjacent PV cells 62. The configuration for microreflector 72 that allows for light rays 20A to be directed in two different directions is explained below. The reflection condition to direct light rays 20A to the immediately adjacent PV cells 62 is described by the relation 2·D·Tan (θ)=(A+B)/2. For example nominal values of A=20 mm, B=50 mm and D=10 mm, then θ≈60°>θ_{C} and β=θ/2≈30°>β_{C}.

FIG. 5 is a close-up view of a portion of solar panel 10 similar to FIG. 2 and shows an example microreflector 72 with facet angles β=30°, ρ=60° and φ=90° that define a sidewall 88, so that the facets 86 are part of a 30°-60°-90° triangle. In this configuration, some light rays 20A undergo a single reflection from facet 86 and are directed generally in the +y direction at a reflectance angle +θ, while some light rays 20A undergo a second reflection from sidewall 88 and are directed generally in the −y direction at a reflectance angle −θ. The single-reflection and double-reflection light rays 20A are generally symmetrical, i.e., the have generally the same absolute reflectance angle θ.

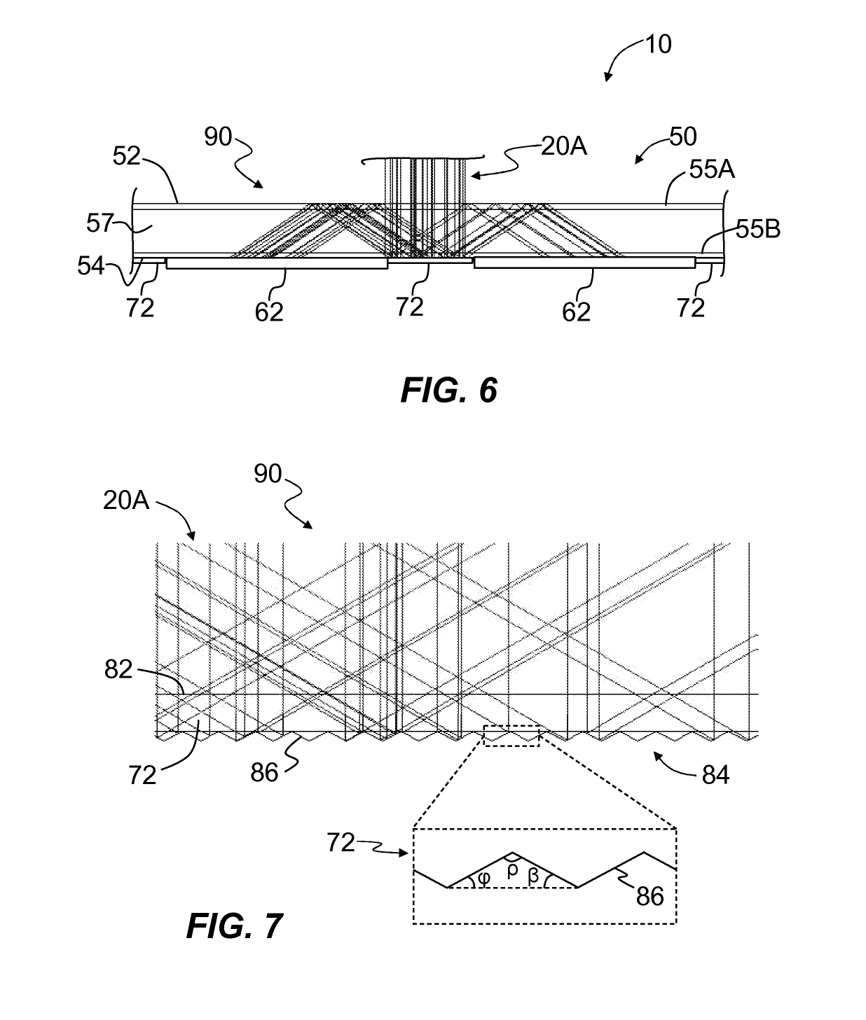

FIG. 6 is similar to FIG. 5 and shows farther-away view illustrating how light rays 20A undergo symmetrical reflection in opposite directions at reflectance angles +θ and −θ. FIG. 6 also shows an example substrate 50 that includes two thin sheets 55A and 55B that define a chamber 57 therebetween. In an example, at least one of sheets 55A and 55B is made from a chemically strengthened glass, such as formed by an ion-exchange process. In an example, at least one of sheets 55A and 55B is made of Gorilla® glass, made by Corning, Inc. of Corning N.Y. In an example, chamber 57 can contain a fluid, e.g., a gas or a liquid.

FIG. 7 is similar to FIG. 6 and shows a close-up view of an example microreflector 72 wherein the facet angles are β=φ=30° and ρ=120°. This geometry has essentially the same effect as the 30°-60°-90° geometry of FIG. 5 in that light rays 20A are directed symmetrically in opposite directions at nominally the same reflectance angles θ=+/−60°.

It is preferred that the ability to direct sunlight portion 20A to PV cells 62 using microreflectors 72 be sustained over a useful range of illumination angles α of sunlight 20 beyond just the normal incidence angle of α=0°. To this end, is desirable that the reflectance angle θ be made as large as possible, consistent with the condition that light rays 20A be made incident upon a PV cell 62. If the reflectance angle θ is made too large, microreflector 72 will generate double reflections that send the reflected light rays 20A off in a direction wherein θ<θ_{C}, or at reflectance angles that do not result in the light rays being incident upon a PV cell 62.

To avoid such double reflections, in an example embodiment facets 86 can be oriented such that light rays 20A reflected by one facet are parallel to the adjacent facet. This occurs when β=φ=30°, such as illustrated in FIG. 7. As it turns out, this condition is entirely consistent with the desirable condition of θ≈60° (β=θ/2) for the example geometry of solar panel 10 as discussed above in connection with FIG. 4 and the conditions for directing light to the immediately adjacent PV cells 60 from a given microreflector 72.

With reference again to the top-down view of solar panel 10 of FIG. 3, the white arrows AR illustrate the directions of reflected light 20A as reflected by microreflectors 72. There are six main reflection directions: The +x direction, the −x direction, the +y direction, the −Y direction, the +45° direction and the 45° direction. In an example, microreflectors 72 located at the corners of PV cells 62 have diagonally oriented facets 86 to create the diagonally oriented reflections.

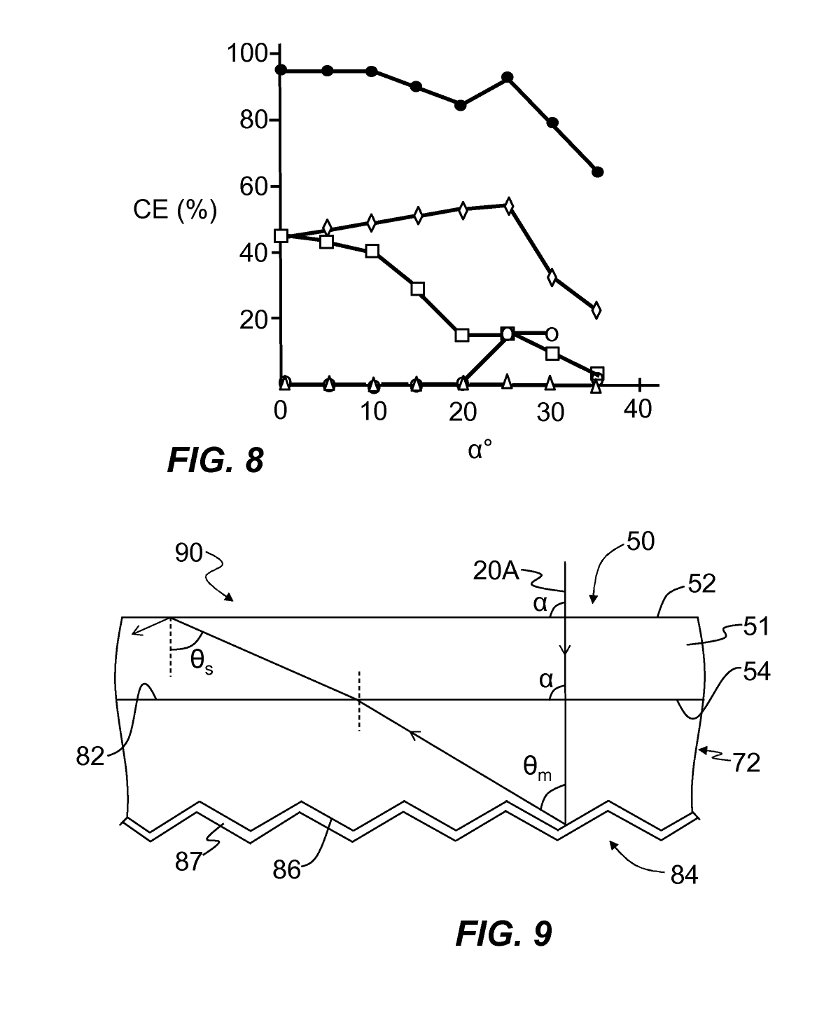

FIG. 8 is a plot of the collection efficient CE (%) as a function of the incidence angle α of light rays 20 at top surface 52 of substrate 50. The collection efficiency CE is the amount of optical power that is incident upon PV cells 62 (through direct illumination as well as via reflection from microreflectors 72) as compared to the total amount of incident optical power. The plot of FIG. 8 is based on a calculation wherein microreflectors 72 have a facet angle of β=φ=30°. In the plot, the symbols ⋄ and □ represent the amount of sunlight 20A reflected to PV cells 32 that are immediately adjacent the microreflector 72, while the symbols Δ and ∘ are for the next-over PV cells. The symbol plots the total collection efficiency CE as the sum of the values of the other plots.

From the plot of FIG. 8, at an incident angle α=0°, the optical power is distributed equally between the PV cells 62 on either side of microreflector 72. As the incidence angle α increases, some of light rays 20A make a double reflection in microreflector 72, which changes the amount of light collected by the adjacent PV cells 62. Also, at α>10°, some of the light rays 20A are imaged outside the PV cell associated with plot □. At α>20°, some of the light rays 20A start hitting the next-over PV cell 62, as shown by plot ∘. At α>25°, some of the light rays 20A get imaged outside PV cell 62 associated with ⋄ and the TIR condition is exceeded so that the collection efficiency CE rapidly decreases.

In an example embodiment, microreflectors 72 have a refractive index nₘ≠nₛ. For example, microreflectors 72 can be made from resin that has a refractive index nₘ up to about 1.6 at visible wavelengths. FIG. 9 is a close-up view similar to FIG. 5 and shows how the difference in refractive indices nₘ and nₛ causes reflected light rays 20A to refract at the interface between bottom surface 54 of substrate 50 and top surface 82 of microreflector 72. If the reflectance angle from facet 86 is denoted θₘ and the reflectance angle at top surface 52 is denoted θₛ, then via Snell's law, nₛ·sinθₛ=nₘ·sinθₘ. Note that when nₛ=nₘ, then θₘ=θₛ=θ. For nₛ=1.5, nₘ=1.6, and θₘ=60°, then θₛ=67.5°. This changes the required thickness D of substrate 50 via the equation 2D·Tan(θₛ)=(A+B)/2. Using A=20 mm, B=50 mm and θₛ=67.5°, solving for the substrate thickness D yields D=7.25 mm, as compared to the previous value of D=10 mm for the case where nₛ=nₘ.

FIG. 9 also illustrates an example embodiment wherein microreflectors optionally include a reflective coating 87 deposited on bottom surface 84 to provide for enhanced reflection from facets 86, particularly in the case where the TIR condition is not satisfied.

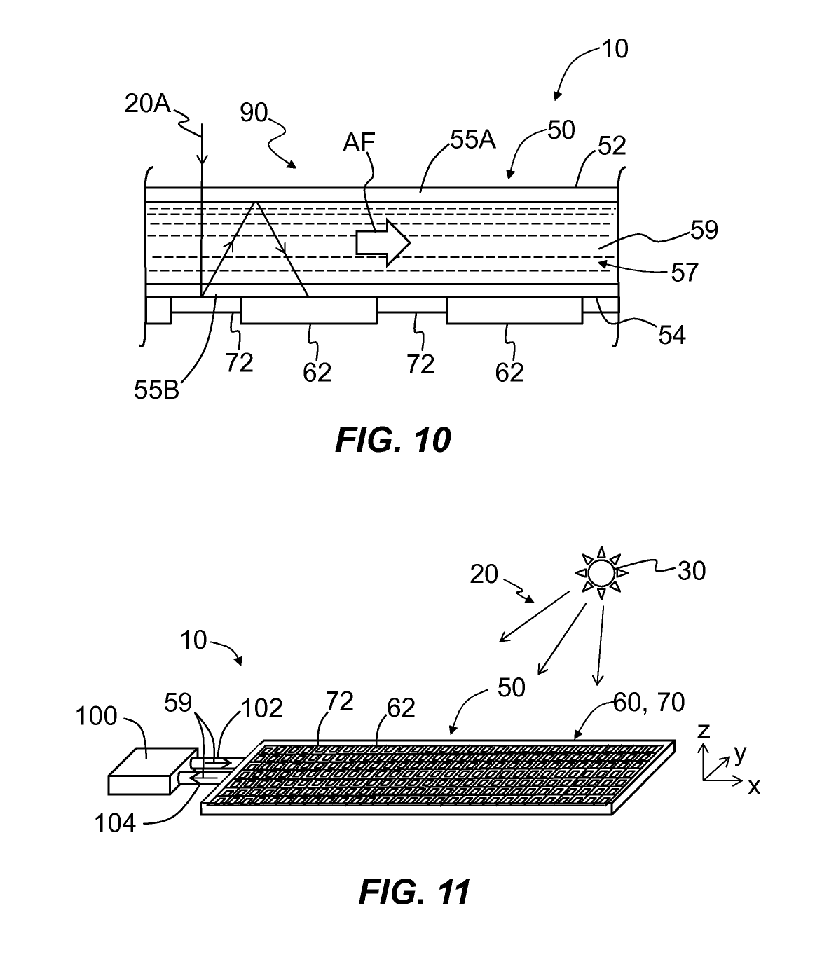

FIG. 10 illustrates an example embodiment similar to that shown in FIG. 6, wherein substrate 50 comprises two thin sheets 55A and 55B that define chamber 57 therebetween. In an example, chamber 57 can be filled with a liquid 59, such as a cooling liquid (e.g., water, glycerin, oil, or suitable combinations thereof). Liquid 59 has a refractive index n_{L}. Arrow AF indicates a flow direction of liquid 59 to effectuate cooling of PV cells 62 by carrying away heat that diffuses through lower sheet 55B and into the liquid.

FIG. 11 is similar to FIG. 1 and illustrates an example cooled solar panel 10 that employs the cooled solar concentrator 90 of FIG. 10. The cooled solar panel 10 includes a liquid source 100 fluidly connected to chamber 57 via input and output conduits 102 and 104. In an example, solar panel 10 is configured with multiple chambers 57 and multiple pairs of input and output conduits 102 and 104.

In the case where water is used for liquid 59, the refractive index n_{L}≈1.33, so that the substrate reflectance angle θₛ≈77° for θₘ=60° and nₘ=nₛ=1.5. Furthermore the critical angle θ_{C}=67.5° between materials having refractive indices 1.33 and 1.5, while the critical angle between air and a material of index 1.5 is about 42°. This is potentially problematic because TIR can happen inside bottom sheet 55B if the incident angle α of sunlight 20 is greater than about 42°. This would prevent sunlight 20 from reaching the PV cells 62. To alleviate this problem, liquid 59 having a refractive index n_{L} greater than that of water and closer to that of sheets 55A and 55B (e.g., nₛ=1.5) can be used. This problem can also be alleviated by using an index-matching fluid between bottom sheet 55B and PV cells 62 as well as microreflectors 72.

It will be apparent to those skilled in the art that various modifications to the preferred embodiments of the disclosure as described herein can be made without departing from the spirit or scope of the disclosure as defined in the appended claims. Thus, the disclosure covers the modifications and variations provided they come within the scope of the appended claims and the equivalents thereto.

What is claimed is:

1. A solar concentrator for concentrating sunlight onto photovoltaic cells of a solar panel, comprising:
a substantially planar substrate that is substantially transparent to the sunlight, the substrate having top and bottom surfaces, wherein the photovoltaic cells are arranged spaced apart from each other and in contact with the bottom surface; and
one or more microreflectors arranged between the photovoltaic cells and in contact with the bottom surface, the microreflectors having angled facets that receive the sunlight through the substrate and reflect the sunlight to the top surface at a reflectance angle that is greater than a total-internal reflection (TIR) critical angle for the substrate top surface, and wherein the sunlight reflected by TIR at the substrate top surface is directed to one or more of the photovoltaic cells.

2. The solar concentrator according to claim 1, wherein the microreflectors reflect the sunlight at the angled facets via TIR.

3. The solar concentrator according to claim 1, wherein the substrate has a thickness D in the range 5 mm≦D≦20 mm.

4. The solar concentrator according to claim 1, wherein the substrate has a thickness D in the range 7 mm≦D≦10 mm.

5. The solar concentrator according to claim 1, wherein the substrate comprises a chemically strengthened glass.

6. The solar concentrator according to claim 5, wherein the chemically strengthened class comprises Gorilla® glass.

7. The solar concentrator of claim 1, wherein the substrate comprises first and second spaced-part sheets that define a chamber therebetween.

8. The solar concentrator of claim 7, further comprising a liquid within the chamber.

9. The solar concentrator of claim 1, wherein the substrate has a solid body.

10. A solar panel for converting sunlight into electrical energy, comprising:
a substantially planar substrate that is substantially transparent to the sunlight and that has top and bottom surfaces;
photovoltaic cells arranged spaced apart from each other and in contact with the bottom surface;
microreflectors arranged between the photovoltaic cells and in contact with the bottom surface, the microreflectors having angled facets that receive a first portion of the sunlight through the substrate and reflect the first portion of the sunlight to the top surface at a reflectance angle that is greater than a total-internal reflection (TIR) critical angle for the substrate top surface, and wherein the first portion of the sunlight reflected by TIR at the substrate top surface is directed to one or more of the photovoltaic cells; and
wherein a second portion of the sunlight is directly received by the photovoltaic cells.

11. The solar panel according to claim 10, wherein the photovoltaic cells have a nominal dimension of 50 mm and the microreflectors have a nominal dimension of 20 mm.

12. The solar panel according to claim 10, wherein the first portion of the sunlight that is reflected by TIR at the substrate top surface and directed to one of the photovoltaic cells is directed to the photovoltaic cells that are immediately adjacent the microreflector at which the first portion of the sunlight is initially received.

13. The solar panel according to claim 10, wherein the substrate comprises chemically strengthened glass.

14. The solar panel according to claim 10, wherein the substrate comprises first and second planar sheets that define a chamber therebetween, with the chamber being fluidly connected to a liquid source that flows a liquid through the chamber.

15. The solar concentrator according to claim 10, wherein the substrate has a thickness D in the range 5 mm≦D≦20 mm.

16. The solar concentrator according to claim 10, wherein the substrate has a thickness D in the range 7 mm≦D≦10 mm.

17. A method of concentrating sunlight onto photovoltaic cells of a solar panel wherein the photovoltaic cells are arranged spaced apart and in contact with a bottom surface of a substrate, comprising:
passing the sunlight through the substrate to irradiate the photovoltaic cells, wherein a portion of the sunlight does not irradiate the photovoltaic cells;
reflecting the portion of the sunlight back through the substrate to the top surface of the substrate at a reflectance angle that is greater than a total-internal reflection (TIR) critical angle for the substrate top surface, thereby forming TIR light; and
directing the TIR light from the top substrate surface to one or more of the photovoltaic cells.

18. The method of claim 17, wherein reflecting the sunlight portion includes performing TIR using a plurality of microreflectors arranged between the spaced-apart photovoltaic cells and in contact with the substrate bottom surface.

19. The method of claim 17, wherein the substrate comprises either a solid body or comprises first and second transparent sheets that define a chamber therebetween that contains a liquid.

20. The solar concentrator according to claim 17, wherein the substrate has a thickness D in the range 7 mm≦D≦10 mm.

21. A method of concentrating sunlight onto photovoltaic cells of a solar panel wherein the photovoltaic cells are arranged spaced apart and in contact with a bottom surface of a substrate having a chamber, comprising:
passing the sunlight through the substrate and chamber to irradiate the photovoltaic cells, wherein a portion of the sunlight does not irradiate the photovoltaic cells;
reflecting the portion of the sunlight back through the substrate and chamber to the top surface of the substrate at a reflectance angle that is greater than a total-internal reflection (TIR) critical angle for the substrate top surface, thereby forming TIR light;
directing the TIR light from the top substrate surface through the chamber to one or more of the photovoltaic cells; and
flowing a cooling liquid through the chamber to cool the photovoltaic cells.

22. The method according to claim 21, wherein the substrate comprises spaced-apart parallel glass plates that define the chamber.
